(19) United States
(12) Patent Application Publication
(10) Pub. No.: US 2008/0157151 A1
(43) Pub. Date: Jul. 3, 2008

(54) CMOS image sensor

(75) Inventor: Byung Tak Jang, Seongnam-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/002,126

(22) Filed: Dec. 13, 2007

(30) Foreign Application Priority Data
Dec. 27, 2006 (KR) 10-2006-0135584

(51) Int. Cl. H01L 27/146

(52) U.S. Cl. 257/292; 257/E27.133

(57) ABSTRACT

Embodiments of the invention relate to a CMOS image sensor. In detail, a CMOS image sensor can have improved sensitivity. The CMOS image sensor includes a photodiode on a semiconductor substrate, a drive transistor including a gate connected to the photodiode, a first grounded electrode and a second electrode connected to a current detector, a transfer transistor connected between the photodiode and the gate to apply voltage or charges generated in the photodiode to the gate, an optional select transistor between the second electrode and the current detector, and an optional reset transistor connected to a power line, configured to reset the photodiode. Accordingly, the CMOS image sensor can read the output of a photodetector without substantial attenuation.

The present application claims priority under 35 U.S.C. 119 and 35 U.S.C. 365 to Korean Patent Application No. 10-2006-0135584 (filed on Dec. 27, 2006), which is hereby incorporated by reference in its entirety.

### BACKGROUND

In general, an image sensor is a semiconductor device that converts an optical image into electrical signals. Image sensors may be classified into Charge Coupled Device (CCD) image sensors, in which individual Metal Oxide Silicon (MOS) capacitors are located closely to each other such that charge carriers are stored in or discharged from the capacitors, and CMOS image sensors, employing a switching mode to sequentially detect pixel outputs by providing a predetermined number of MOS transistors to each pixel, manufactured using a CMOS technology and using peripheral devices, such as a control circuit and a signal processing circuit.

A CMOS image sensor that converts information on a subject into electrical signals includes signal processing chips having photodiodes, an amplifier, an A/D converter, an internal voltage generator, a timing generator and digital logic on one chip. Accordingly, the CMOS image sensor is particularly advantageous in terms of space, power and cost reduction. A CCD is manufactured through a special process. However, the CMOS image sensor can be manufactured in large quantities using CMOS processing on a low-priced silicon wafer, and is advantageous in terms of the integration degree.

In the CMOS image sensor, light is converted into an electric signal from electric charges stored in a photodiode. When the amount of incident light is insufficient due to darkness, a reduced amount of charge is stored in the photodiode, SO the output signal may not be distinguished from noise.

### SUMMARY

An exemplary CMOS image sensor may comprise a photodiode on a semiconductor substrate; a drive transistor including a gate connected to the photodiode, a first grounded electrode and a second electrode connected to a current detector; a transfer transistor connected between the photodiode and the gate, configured to apply a voltage or charge(s) generated in the photodiode to the gate; an optional select transistor between the second electrode and the current detector; and an optional reset transistor connected to a power line, configured to reset the photodiode.

### BRIEF DESCRIPTION OF THE DRAWINGS

FIG. 1 is a circuit diagram showing a unit pixel of a voltage detection type CMOS image sensor having four transistors; and

FIG. 2 is an equivalent circuit diagram showing a unit pixel of a voltage detection type CMOS image sensor according to embodiments of the invention.

### DETAILED DESCRIPTION OF THE EMBODIMENTS

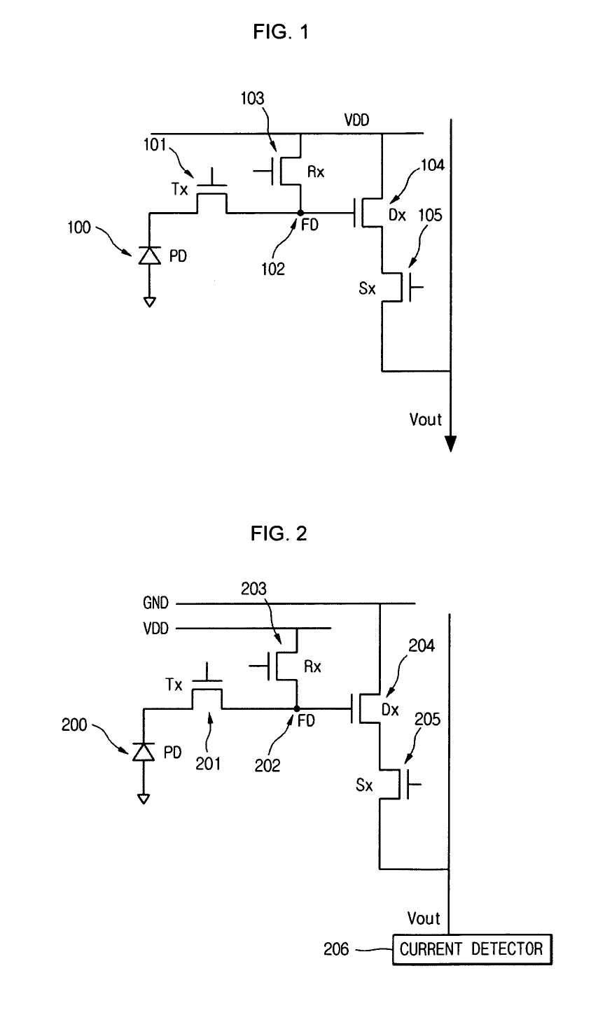

FIG. 1 is a circuit diagram showing a unit pixel of a voltage detection type CMOS image sensor having four transistors according to an embodiment.

As shown in FIG. 1, a voltage detection type CMOS image sensor includes a photodetector 100, a transfer transistor 101, a reset transistor 103, a drive transistor 104, and a select transistor 105. The photodetector 100 includes a photodiode that generates electrical charges from optical energy (e.g., light), and the transfer transistor Tx 101 receives an enable or read signal at the gate thereof and carries the charges collected in the photodetector 100 to a floating diffusion area FD 102 when the enable or read signal is active. The reset transistor 103 resets the FD area 102 by receiving a reset signal at the gate thereof, setting the voltage of the FD area 102 to a desired level (e.g., VDD), and discharging the charges of the FD area 102. The drive transistor 104 receives the voltage of the FD area 102 at the gate thereof, and therefore, serves as a source follower (and optionally, a buffer amplifier), and the select transistor 105 outputs a voltage from the drive transistor Dx 104 in response to addressing functions (which may be generated and/or executed elsewhere on the CMOS image sensor).

The voltage detection type CMOS image sensor can read the voltage of the photodetector 100 when the select transistor 105 and the transfer transistor 101 of the unit pixel to be read are turned on. In such a state, when the reset transistor 103 is turned on, the voltage of the photodetector 100 is initialized. Then, if the initialized voltage is subtracted from the voltage of the photodetector 100 (or the voltage of the photodetector 100 is subtracted from the initialized voltage), the resultant value becomes the voltage value proportional to the amount of light accumulated in the photodetector 100 after the previous reset. Such a scheme of reading and comparing the voltages before and after the reset may effectively remove an adverse influence derived from device variations in the unit pixels across the image sensor.

Since the drive transistor 104 serves as a source follower, the drain voltage of the drive transistor 104 increases as the output voltage of the photodetector 100 increases (or decreases as the amount of charge in the photodetector 100 decreases). Since the body of the drive transistor 104 is fixed to the ground GND, a body effect increases as the source voltage of the drive transistor 104 increases, so the threshold voltage of the drive transistor 104 increases. Thus, voltage variations in the photodetector 100, particularly small voltages in the photodetector 100, may not be directly transferred to the drain of the drive transistor 104.

Embodiments of the invention can provide the CMOS image sensor with improved sensitivity by converting the voltage of the photodetector into electric current and outputting the electric current.

Hereinafter, a CMOS image sensor according to other embodiment(s) will be described in detail with reference to the accompanying drawings.

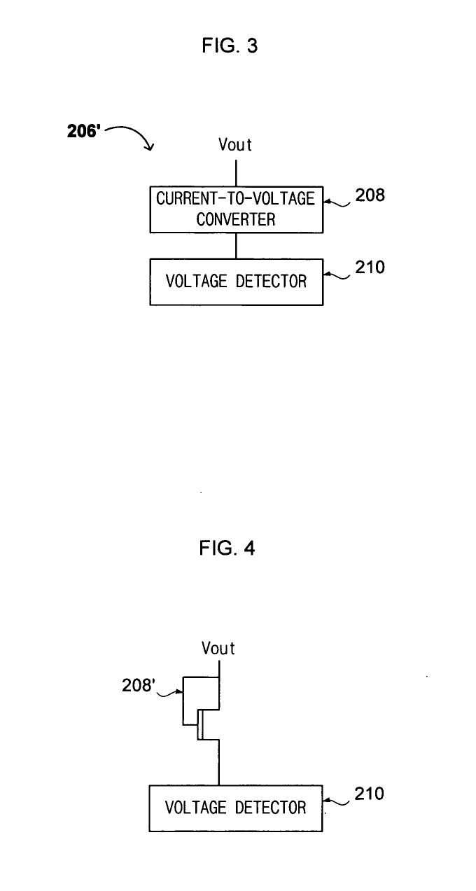

FIG. 2 is an equivalent circuit diagram showing a unit pixel of a current detection type CMOS image sensor according to the other embodiment(s).

As shown in FIG. 2, the current detection type CMOS image sensor includes a photodetector 200, a transfer transistor 201, a reset transistor 203, a drive transistor 204, and a select transistor 205. The photodetector 200 includes a photodiode that generates electrical charges from optical energy, and the transfer transistor 201 receives signals at the gate thereof and transfers the charges collected in the photodetector 200 to a FD area 202. The reset transistor 203 resets the FD area 202 by receiving reset signals at the gate thereof, setting the voltage of the FD area 202 to a desired level (e.g., VDD or ground), and discharging the charges of the FD area 102. Alternatively, the terminal of reset transistor 203 opposite to FD area 202 may be coupled to a different power rail (e.g., VCC) or to a reference voltage, such as VCC/2 (which can put the drive transistor 204 is a relatively linear response range). The drive transistor 204 receives signals from the FD area 202 at the gate thereof and serves as a source follower (and optionally, a buffer amplifier), and the select transistor 205 outputs a voltage from the drive transistor Dx 104 in response to addressing functions (which may be generated and/or executed elsewhere on the CMOS image sensor).

In order to improve the sensitivity of the CMOS image sensor, the source of the drive transistor 204 is grounded, and a current detector 206 is connected to the drain of the drive transistor 204 to measure electric current output by the unit pixel, so that the body effect can be reduced, avoided, or prevented when reading the output voltage of the photodetector 200.

As the CMOS image sensor has the construction as described above, the output signals from the unit pixels are transmitted in the form of electric current, ill instead of voltage. Accordingly, the output signals have strong characteristics against noise in the chip as compared with the case where the output signals are in the form of voltage, so the output signals can be amplified at a high rate in an amplifier, and thus, small differences in photocharges stored in the photodetector 200 (even at low levels) can be relatively easily detected.

Further, since DC level adjustment is easily achieved through addition or subtraction of a predetermined value in the current detection case, as compared with a case of reading the output signals in the form of voltage, analog circuit design can be easily implemented. For example, the current detector can be a conventional analog or digital current detector (in the latter case, the detector may further comprise an analog-to-digital converter [ADC]).

In the case of the above drive transistor 204, electric current proportional to the square of the gate voltage flows through the drive transistor 204 in a saturation state, so a micro value can be easily read in a dark state (e.g., in a high voltage state of the photodetector 200).

According to the related voltage detection type CMOS image sensor, since constant current flows in the source of the drive transistor 204, the voltage of the photodetector 200 must be higher than the threshold voltage of the drive transistor 204 in order to ensure the operation of a current source. However, according to the current detection type CMOS image sensor (e.g., as shown in FIG. 2), since the drain current flows even when the gate voltage of the drive transistor 204 is lower than the threshold voltage of the drive transistor 204, the output value of the photodetector 200 can be read. As a result, substantially all output voltages of the photodetector 200 can be read, and the noise threshold of the pixel is considerably smaller than the voltage detection type image sensor.

In order to convert the output value from an electric current into voltage, as shown in FIG. 3, the CMOS image sensor may comprise a current-to-voltage converter 208 and a voltage detector 210 for outputting the detected voltage (e.g., as a single- or multi-bit digital signal). In an alternative embodiment, a conventional analog-to-digital converter may replace output block 206′ (see FIG. 3). As shown in FIG. 4, a MOSFET having the same current-voltage characteristics (e.g., as drive transistor 204) is fabricated in the form of a diode (e.g., a transistor 208′ having a gate connected to a drain thereof), and electric current Vout is supplied to the diode 208′, so that the voltage of the photodetector can be obtained (e.g., in voltage detector 210). The output of voltage detector 210 may be further processed by signal processing logic in the CMOS image sensor to generate an image data file for subsequent display on an image viewing terminal (e.g., a computer monitor, a cellular phone or PDA display screen, a view screen in a motor vehicle, etc.).

The current-to-voltage detection type CMOS image sensor can read the output of the photodetector 200 when the select transistor 205 and the transfer transistor 201 of the unit pixel to be read are turned on. In such a state, when the reset transistor 203 is turned on, the output of the photodetector 200 is initialized. Then, if the initialized voltage is subtracted from the output of the photodetector 200 (or vice versa, depending on the voltage at the drain of the reset transistor 203), the resultant value becomes a voltage proportional to the amount of light accumulated in the photodetector 200 after the previous reset.

The output signals before and after the reset are read and compared, so that an adverse influence derived from device variations in the unit pixels can be effectively removed. That is, according to the current-to-voltage detection type CMOS image sensor, an output of the photodetector 200 can be read without attenuation, and is transmitted in the form of electric current, so the output signals have strong characteristics against noise in the chip.

Further, since the noise component is relatively small, the output signals can be amplified at a high rate when the output signals are small. In addition, since the output signals are transmitted in the form of electric current, analog circuit design of the subsequent stage is relatively easy.

Furthermore, substantially all values of the photodetector 200 can be transmitted without attenuation, and the output of the photodetector 200 can be precisely read in low luminance.

Embodiments of the invention may have the following advantages. First, the CMOS image sensor can read the output of the photodetector without attenuation, and transmit the output of the photodetector in the form of electric current, so the output signals have strong characteristics against noise in the chip. Further, since the noise component is relatively small, the output signals can be amplified at a high rate when the output signals are small. In addition, since the output signals are transmitted in the form of electric current, analog circuit design of the subsequent stage is relatively easy.

Second, substantially all values of the photodetector can be transmitted without significant attenuation, and the output of the photodetector can be precisely read in low luminance.

Third, the CMOS image sensor outputs the photodetector charges in the form of electric current, thereby improving the sensitivity of the sensor and its dynamic range.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A CMOS image sensor comprising:
a photodiode on a semiconductor substrate;
a drive transistor including a gate connected to an output of the photodiode, a first grounded electrode, and a second electrode connected to a current detector; and
a transfer transistor between the photodiode and the gate to apply voltage or charges generated in the photodiode to the gate.

2. The CMOS image sensor as claimed in claim 1, further comprising a select transistor between the second electrode and the current detector.

3. The CMOS image sensor as claimed in claim 1, further comprising a reset transistor connected to a power line and configured to reset the photodiode.

4. The CMOS image sensor as claimed in claim 2, further comprising a reset transistor connected to a power line and configured to reset the photodiode.

5. The CMOS image sensor as claimed in claim 1, wherein the output of the photodiode is a floating diffusion region.

6. The CMOS image sensor as claimed in claim 5, further comprising a 1reset transistor connected to a power rail and configured to reset the floating diffusion region.

7. The CMOS image sensor as claimed in claim 5, wherein the floating diffusion region is also a node between an output of the transfer transistor and the gate.

8. The CMOS image sensor as claimed in claim 1, wherein the second electrode of the drive transistor is connected to a diode.

9. The CMOS image sensor as claimed in claim 8, wherein the diode comprises a transistor in which gate and drain electrodes thereof are interconnected.

10. The CMOS image sensor as claimed in claim 1, wherein an output of the photodiode is converted into electric current by the drive transistor.

11. The CMOS image sensor as claimed in claim 1, wherein drain current flows when a gate voltage of the drive transistor is smaller than a threshold voltage of the drive transistor.

12. The CMOS image sensor as claimed in claim 1, wherein electric current proportional to a square of gate voltage flows in the drive transistor in a saturation state.

13. The CMOS image sensor as claimed in claim 1, wherein the transfer transistor transfers electrical charges from the photodiode to a floating diffusion area.

14. The CMOS image sensor as claimed in claim 13, wherein the reset transistor resets the photodiode by discharging electrical charges from the floating diffusion area.

15. The CMOS image sensor as claimed in claim 1, wherein the drive transistor serves as a source follower.

16. The CMOS image sensor as claimed in claim 15, wherein the drive transistor further serves as a buffer amplifier.

17. The CMOS image sensor as claimed in claim 8, wherein the diode converts an output current of the drive transistor into a voltage.
